(19) United States
(12) Patent Application Publication
(10) Pub. No.: US 2017/0076914 A1
(43) Pub. Date: Mar. 16, 2017

(54) PLASMA PROCESSING APPARATUS

(71) Applicant: TOKYO ELECTRON LIMITED, Tokyo (JP)

(72) Inventor: Toshihisa NOZAWA, Miyagi (JP)

(73) Assignee: TOKYO ELECTRON LIMITED, Tokyo (JP)

(21) Appl. No.: 15/263,486

(22) Filed: Sep. 13, 2016

(30) Foreign Application Priority Data
Sep. 14, 2015 (JP) 2015-180850

(51) Int. Cl. H01J 37/32; C23C 16/50

(52) U.S. Cl. CPC H01J 37/32009; C23C 16/50; H01J 37/3244; H01J 2237/334

(57) ABSTRACT

Disclosed is a plasma processing apparatus including a processing container, a placing table provided in the processing container and configured to place a substrate thereon, a plasma generating mechanism attached to the processing container to face the placing table and configured to supply electronic energy for plasma generation into the processing container, a lattice-shaped member or a plurality of rod-shaped members provided at a position closer to the placing table than an intermediate position between the placing table and the plasma generating mechanism, and a moving mechanism configured to move the lattice-shaped member or the plurality of rod-shaped members and the placing table relative to each other.

### CROSS-REFERENCE TO RELATED APPLICATIONS

This application is based on and claims priority from Japanese Patent Application No. 2015-180850 filed on Sep. 14, 2015 with the Japan Patent Office, the disclosure of which is incorporated herein in its entirety by reference.

### TECHNICAL FIELD

Various aspects and exemplary embodiments of the present disclosure relate to a plasma processing apparatus.

### BACKGROUND

In a semiconductor manufacturing process, a plasma processing apparatus, which executes a plasma processing for the purpose of, for example, deposition or etching of a thin film, is widely used. The plasma processing apparatus may be, for example, a plasma chemical vapor deposition (CVD) apparatus, which performs a thin film deposition processing, and a plasma etching apparatus, which performs an etching processing.

The plasma processing apparatus includes, for example, a processing container configured to process a processing target substrate and a placing table configured to provide the processing target substrate in the processing container. In addition, the plasma processing apparatus includes, for example, a plasma generating mechanism attached to the processing container to face the placing table and configured to supply electromagnetic energy, such as, for example, microwaves and RF waves, in order to generate plasma of a processing gas in the processing container.

However, in the plasma processing apparatus, since ions in the plasma are incident on the processing target substrate from a direction perpendicular thereto, the processing target substrate may be damaged in some cases. In addition, in the case where the plasma processing apparatus is a plasma CVD apparatus, there is a probability that film formability may be deteriorated when the ions in the plasma are incident on the processing target substrate from the direction perpendicular thereto. For example, it is assumed that the plasma CVD apparatus performs a film forming processing on the processing target substrate having a trench formed therein. In this case, when the ions in the plasma are incident on the processing target substrate from the direction perpendicular thereto, the quantity of irradiated ions is lower at the side portion of the trench than at the bottom portion of the trench. Thus, a film forming speed is reduced in some cases.

In contrast, there is a technology of increasing the quantity of ions to be incident on the processing target substrate by providing a plurality of conductive rods at an intermediate position between the placing table and the plasma generating mechanism, and selectively accelerating electrons in the plasma to the processing target substrate side using a magnetic field formed around the plurality of conductive rods. See, for example, Japanese Patent Laid-Open Publication No. 2000-012285.

### SUMMARY

In one exemplary embodiment, the present disclosure provides a plasma processing apparatus including a processing container, a placing table provided in the processing container and configured to place a substrate thereon, a plasma generating mechanism attached to the processing container to face the placing table and configured to supply electronic energy for plasma generation into the processing container, a lattice-shaped member or a plurality of rod-shaped members provided at a position closer to the placing table than an intermediate position between the placing table and the plasma generating mechanism, and a moving mechanism configured to move the lattice-shaped member or the plurality of rod-shaped members and the placing table relative to each other.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical-sectional view illustrating a schematic configuration of a plasma processing apparatus according to an exemplary embodiment.

FIG. 2 is a plan view illustrating an installation aspect of a plurality of rod-shaped members according to an exemplary embodiment.

FIG. 3 is a vertical-sectional view illustrating a schematic configuration of a rotary seal mechanism according to an exemplary embodiment.

FIG. 4A is a view for explaining a mechanism for uniformizing a plasma processing by relative movement between the plurality of rod-shaped members and a susceptor according to an exemplary embodiment.

FIG. 4B is a view for explaining a mechanism for uniformizing a plasma processing by relative movement between the plurality of rod-shaped members and the susceptor according to an exemplary embodiment.

FIG. 4C is a view for explaining a mechanism for uniformizing a plasma processing by relative movement between the plurality of rod-shaped members and the susceptor according to an exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the conventional technology, it has not been considered to make the ions in the plasma inclined uniformly on the processing target substrate on the placing table from an inclined direction.

That is, in a technology of increasing the quantity of ions to be incident on the processing target substrate using a plurality of conductive rods, the processing target substrate may be damaged or film formability may be deteriorated because the ions in the plasma are incident on the processing target substrate from the direction perpendicular thereto.

Here, it may be contemplated to make the ions in the plasma incident on the processing target substrate on the placing table from an inclined direction. However, when the ions in the plasma are simply incident on the processing target substrate on the placing table from an inclined direction, it is difficult to perform a uniform plasma processing on the entire surface of the processing target substrate. For example, in a case where the plasma processing apparatus is a plasma CVD apparatus, since a plasma density is uneven, the ions are unevenly irradiated to the side portion of the trench in the processing target substrate from the inclined direction, and the uniformity of a film forming speed in a peripheral direction of the processing target substrate is not maintained. Therefore, there is a need to make the ions in the plasma incident uniformly on the processing target substrate on the placing table from an inclined direction.

In an exemplary embodiment, the present disclosure provides a plasma processing apparatus including a processing container, a placing table provided in the processing container and configured to place a substrate thereon, a plasma generating mechanism attached to the processing container to face the placing table and configured to supply electronic energy for plasma generation into the processing container, a lattice-shaped member or a plurality of rod-shaped members provided at a position closer to the placing table than an intermediate position between the placing table and the plasma generating mechanism, and a moving mechanism configured to move the lattice-shaped member or the plurality of rod-shaped members and the placing table relative to each other.

In the above-described plasma processing apparatus, the moving mechanism moves the placing table relative to the lattice-shaped member or the plurality of rod-shaped members by rotating the placing table.

In the above-described plasma processing apparatus, the moving mechanism moves the plurality of rod-shaped members relative to the placing table by reciprocating the plurality of rod-shaped members in a direction parallel to the placing table, which is a direction intersecting with the rod-shaped members.

In the above-described plasma processing apparatus, a distance between the lattice-shaped member or the plurality of rod-shaped members and the placing table is equal to or less than a pitch of the lattice-shaped member or the plurality of rod-shaped members.

The above-described plasma processing apparatus further includes a high frequency power source configured to apply a bias electric power to the placing table.

According to an aspect of the plasma processing apparatus of the present disclosure, ions in plasma may be incident uniformly on the processing target substrate on the placing table from an inclined direction.

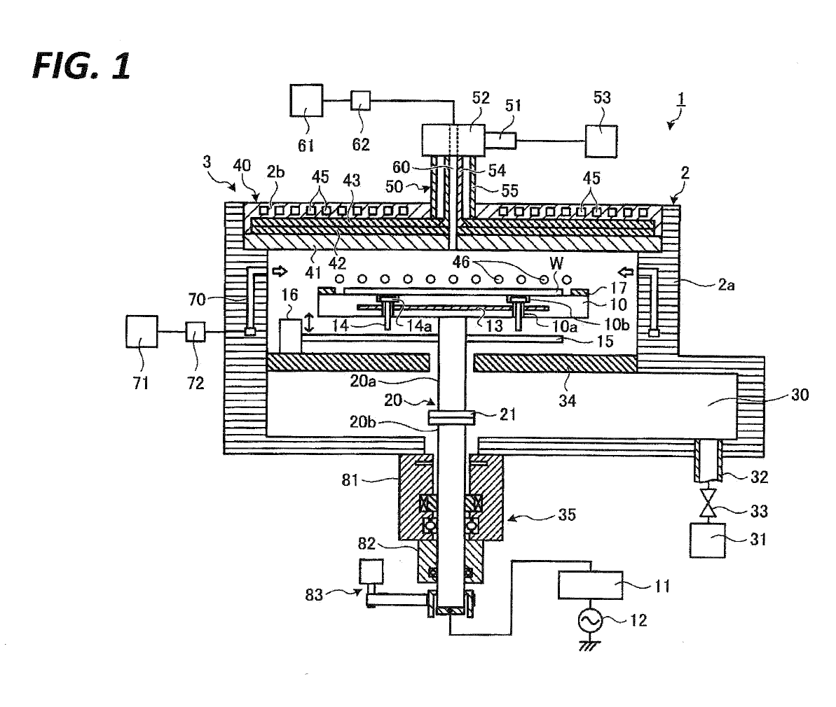

Hereinafter, various exemplary embodiments will be described in detail with reference to the accompanying drawings. FIG. 1 is a vertical-sectional view illustrating a schematic configuration of a plasma processing apparatus according to an exemplary embodiment. In addition, in an exemplary embodiment, descriptions will be made on, by way of example, a case where the plasma processing apparatus 1 performs a plasma chemical vapor deposition (CVD) processing on a surface of a wafer W to form, for example, a silicon nitride (SiN) film on the surface of the wafer W. In addition, in the specification and the drawings, constituent elements having substantially the same functional configuration are designated by the same reference numerals, and the overlapping descriptions thereof will be omitted.

The plasma processing apparatus 1 includes a processing container 2, the inside of which is kept hermetically sealed. The processing container 2 includes a substantially cylindrical main body portion 2a with the top opened, and a substantially disc-shaped cover 2b that hermetically closes the opening of the main body portion 2a. The main body portion 2a and the cover 2b are formed of a metal, such as, for example, aluminum. In addition, the main body portion 2a is grounded by a ground wire (not illustrated).

A susceptor 10 is provided in the processing container 2 and serves as a placing table on which the wafer W that is a processing target substrate is placed. The susceptor 10 has, for example, a disc shape. The susceptor 10 is connected with a bias high-frequency power source 12 through a matcher 11 and a slip ring 100 to be described later. The high-frequency power source 12 outputs a high-frequency electric power (bias electric power) of a constant frequency suitable to control the energy of ions drawn into the wafer W, for example, 13.56 MHz. In addition, although not illustrated, an electrostatic chuck for electrostatic adsorption of the wafer W may be provided on the susceptor 10 and may electrostatically adsorb the wafer W to the susceptor 10. In addition, a heater 13 may be provided in the susceptor 10 to heat the wafer W to a predetermined temperature. The supply of the electric power to the heater 13 is also performed via the slip ring 100 to be described later.

Further, lift pins 14 are provided below the susceptor 10 to support and vertically move the wafer W from below. Each lift pin 14 is inserted through a through-hole 10a penetrating the susceptor 10 vertically, is freely movable relative to the susceptor 10, and is formed longer than the thickness of the susceptor 10 so as to protrude from the upper surface of the susceptor 10. A lift arm 15 is provided below the lift pins 14 to push the lift pins upward. The lift arm 15 is configured to be freely vertically movable by a lift mechanism 16. The lift pins 14 are not connected to the lift arm 15. When the lift arm 15 is moved down, the lift pins 14 and the lift arm 15 are separated from each other. An upper end 14a of each lift pin 14 has a diameter greater than the through-hole 10a. Therefore, the lift pin 14 is not removed from the through-hole 10a, but is caught by the susceptor 10 even when the lift arm 15 retreats downward. Further, a recess 10b, which has a diameter and thickness greater than the upper end 14a of the lift pin 14, is formed in an upper end of the through-hole 10a, such that the upper end 14a does not protrude from the upper surface of the susceptor 10 in a state where the lift pin 14 is caught by the susceptor 10. In addition, FIG. 1 illustrates a state where the lift arm 15 is moved down so that the lift pins 14 are caught by the susceptor 10.

An annular focus ring 17 is provided on the upper surface of the susceptor 10 so as to surround the wafer W. The focus ring 17 is formed of an insulation material, such as, for example, ceramic or quartz. Plasma generated in the processing container 2 is converged on the wafer W by action of the focus ring 17, and accordingly, the in-plane uniformity of the plasma processing on the wafer W is improved.

The central portion of the lower surface of the susceptor 10 is supported by, for example, a centrally hollow cylindrical support shaft 20. The support shaft 20 is provided to extend vertically downward and penetrate a bottom surface of the main body portion 2a of the processing container 2 vertically. The support shaft 20 includes an upper shaft 20a, which comes in contact with the susceptor 10, and a lower shaft 20b, which is connected to the upper shaft 20a via a flange 21 provided at a lower end of the upper shaft 20a. The upper shaft 20a and the lower shaft 20b are formed of, for example, an insulating member.

The bottom portion of the main body portion 2a of the processing container 2 is provided with, for example, an exhaust chamber 30 that protrudes laterally from the main body portion 2a. An exhaust mechanism 31 for exhausting the inside of the processing container 2 is connected to a bottom surface of the exhaust chamber 30 through an exhaust pipe 32. An adjustment valve 33 is provided to the exhaust pipe 32 to adjust an exhaust capacity by the exhaust mechanism 31.

An annular baffle plate 34 for uniformly exhausting the inside of the processing container 2 is provided above the exhaust chamber 30 and below the susceptor 10 with a predetermined gap from an outer surface of the support shaft 20. The baffle plate 34 includes, over the entire periphery thereof, openings (not illustrated) penetrating the baffle plate 34 in a thickness direction.

A microwave supply unit 3 is provided in a ceiling side opening of the processing container 2 to supply microwaves for plasma generation. The microwave supply unit 3 has a radial line slot antenna 40. The radial line slot antenna 40 is attached to the processing container 2 to face the susceptor 10. The radial line slot antenna 40 includes a microwave-transmitting plate 41, a slot plate 42, and a slow-wave plate 43. The microwave-transmitting plate 41, the slot plate 42 and the slow-wave plate 43 are stacked one above another from the lower side in this order and provided in the opening of the main body portion 2a of the processing container 2. An upper surface of the slow-wave plate 43 is covered with the cover 2b. Further, the center of the radial line slot antenna 40 is located at a position substantially coinciding with the center of rotation of the support shaft 20.

A seal member (not illustrated) such as, for example, an O-ring hermetically seals a gap between the microwave-transmitting plate 41 and the main body portion 2a. The microwave-transmitting plate 41 is formed of dielectrics, such as, for example, quartz, Al₂O₃, or AlN, and the microwave-transmitting plate 41 transmits microwaves.

The slot plate 42 provided on an upper surface of the microwave-transmitting plate 41 is provided with plurality of slots, and the slot plate 42 functions as an antenna. The slot plate 42 is fowled of a conductive material, such as, for example, copper, aluminum, or nickel.

The slow-wave plate 43, provided on an upper surface of the slot plate 42, is formed of a low-loss dielectric material, such as, for example, quartz, Al₂O₃, or AlN, and shortens the wavelength of microwaves.

The cover 2b, which covers the upper surface of the slow-wave plate 43, has plurality of annular flow paths 45 formed therein to circulate, for example, a coolant. The cover 2b, the microwave-transmitting plate 41, the slot plate 42, and the slow-wave plate 43 are adjusted to a predetermined temperature by the coolant flowing in the flow paths 45.

A coaxial waveguide 50 is connected to the central portion of the cover 2b. A microwave generation source 53 is connected to an upper end of the coaxial waveguide 50 through a rectangular waveguide 51 and a mode converter 52. The microwave generation source 53 may be provided outside the processing container 2, and may generate microwaves of, for example, 2.45 GHz.

The coaxial waveguide 50 has an inner conductor 54 and an outer pipe 55. The inner conductor 54 is connected to the slot plate 42. The side of the inner conductor 54 toward the slot plate 42 has a conical shape, and is configured to efficiently propagate microwaves to the slot plate 42.

With this configuration, microwaves generated from the microwave generation source 53 are sequentially propagated through the rectangular waveguide 51, the mode converter 52, and the coaxial waveguide 50, and are compressed so that the wavelength is shortened in the slow-wave plate 43. Then, circularly polarized microwaves from the slot plate 42 penetrate the microwave-transmitting plate 41 and are irradiated into the processing container 2. The processing gas is converted into plasma by the microwaves in the processing container 2, and a plasma processing is performed on the wafer W by the plasma. Further, the microwave-transmitting plate 41, the slot plate 42, and the slow-wave plate 43 (i.e., the radial line slot antenna 40) correspond to an example of the plasma generating mechanism which is attached to the processing container 2 to face the susceptor 10 and configured to supply electronic energy for plasma generation.

In addition, a plurality of rod-shaped members 46 are provided at a position closer to the susceptor 10 than an intermediate position between the susceptor 10 and the radial line slot antenna 40. The plurality of rod-shaped members 46 are formed of an insulation material, for example, ceramic or quartz.

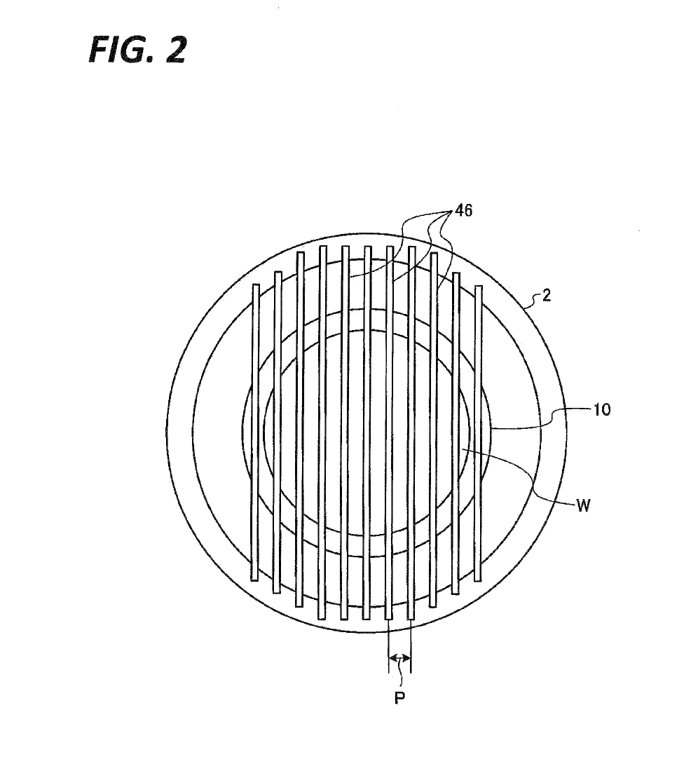

FIG. 2 is a plan view illustrating an installation aspect of the rod-shaped members according to an exemplary embodiment. As illustrated in FIG. 2, the plurality of rod-shaped members 46 are fixed to the processing container 2 in a state of crossing the upper side of the susceptor 10 in a direction parallel to the susceptor 10. A distance between the plurality of rod-shaped members 46 and the susceptor 10 is set to a value equal to or less than a pitch P of the rod-shaped members 46, for example, 1 cm to 5 cm.

Reference is made back to FIG. 1. A rotary seal mechanism 35 is provided on a lower end surface of the bottom portion of the main body portion 2a of the processing container 2, i.e., outside the processing container 2 to hermetically seal a gap between the support shaft 20 and the main body portion 2a and to rotate the susceptor 10 via the support shaft 20 about a vertical axis. The rotary seal mechanism 35 moves the susceptor 10 relative to the rod-shaped members 46 by rotating the susceptor 10. The rotary seal mechanism 35 corresponds to an example of the moving mechanism which moves the rod-shaped members 46 and the susceptor 10 relative to each other. The rotary seal mechanism 35 will be described later in detail.

A first processing gas supply pipe 60 is provided in the ceiling side central portion of the processing container 2, i.e., the central portion of the radial line slot antenna 40. The first processing gas supply pipe 60 vertically penetrates the radial line slot antenna 40, and one end of the first processing gas supply pipe 60 is opened at a lower surface of the microwave-transmitting plate 41. In addition, the first processing gas supply pipe 60 penetrates the inside of the inner conductor 54 of the coaxial waveguide 50, and is further inserted through the inside of the mode converter 52. The other end of the first processing gas supply pipe 60 is connected to a first processing gas supply source 61.

The first processing gas supply source 61 is configured to individually supply processing gases, for example, trisilyl amine (TSA), N₂ gas, H₂ gas, and Ar gas. Among those, TSA, N₂ gas, and H₂ gas are source gasses for formation of an SiN film, and Ar gas is a gas for plasma excitation. Hereinafter, the processing gases may be referred to as a “first processing gas” in some cases. In addition, a supply device group 62 including, for example, a valve or a flow rate regulator for controlling the flow of the first processing gas is provided in the first processing gas supply pipe 60. The first processing gas supplied from the first processing gas supply source 61 is supplied into the processing container 2 through the first processing gas supply pipe 60, and flows vertically downward toward the wafer W placed on the susceptor 10.

In addition, as illustrated in FIG. 1, second processing gas supply pipes 70 are provided in an inner circumferential surface of the upper portion of the processing container 2. A plurality of second processing gas supply pipes 70 is provided equidistantly along the inner circumferential surface of the processing container 2. A second processing gas supply source 71 is connected to the second processing gas supply pipes 70. The second processing gas supply source 71 is configured to individually supply processing gases, for example, trisilyl amine (TSA), N₂ gas, H₂ gas, and Ar gas. Hereinafter, the processing gases may be referred to as a “second processing gas” in some cases. In addition, a supply device group 72 including, for example, a valve or a flow rate regulator for controlling the flow of the second processing gas is provided in the second processing gas supply source 71. The second processing gas supplied from the second processing gas supply source 71 is supplied into the processing container 2 through the second processing gas supply pipes 70, and flows toward the outer circumference of the wafer W placed on the susceptor 10. In this way, the first processing gas from the first processing gas supply pipe 60 is supplied to the central portion of the wafer W, and the second processing gas from the second processing gas supply pipes 70 is supplied to the outer circumferential portion of the wafer W.

Further, the processing gases supplied respectively from the first processing gas supply pipe 60 and the second processing gas supply pipes 70 into the processing container 2, may be the same or different kinds of gases, and may be supplied respectively at independent flow rates, or at an arbitrary flow rate ratio.

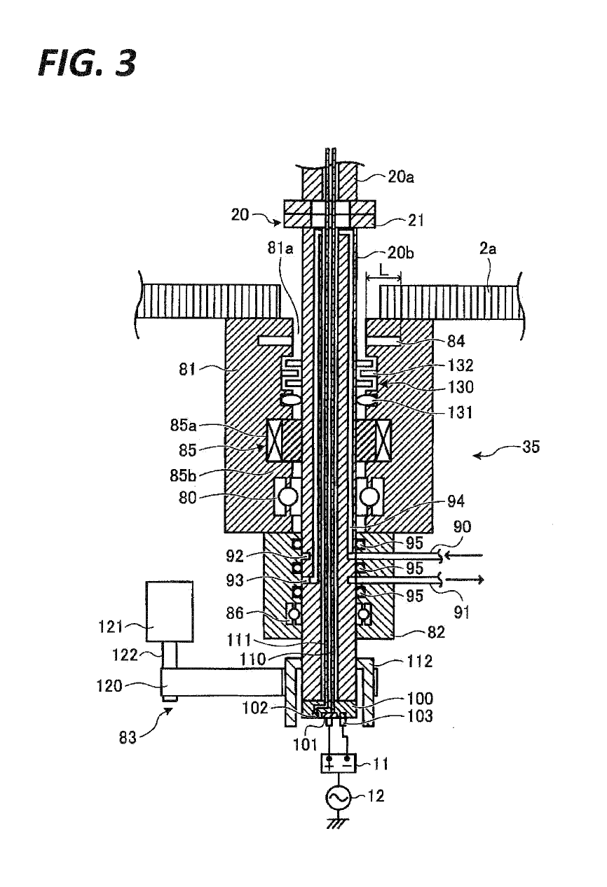

Next, the rotary seal mechanism 35 will be described in detail. FIG. 3 is a vertical-sectional view illustrating a schematic configuration of a rotary seal mechanism according to an exemplary embodiment. The rotary seal mechanism 35 includes a casing 81 configured to hold the support shaft 20 via a bearing 80, a rotary joint 82 connected to a lower end of the casing, and a rotation driving mechanism 83 configured to rotate the support shaft 20.

The casing 81 has an opening 81 a having an inner diameter greater than an outer diameter of the support shaft 20, and the lower shaft 20b of the support shaft 20 is inserted through the opening 81a. An upper end portion of the casing 81 is fixed to the bottom portion of the main body portion 2a of the processing container 2 via, for example, a bolt (not illustrated), and a gap between the upper end portion of the casing 81 and the lower end surface of the main body portion 2a is hermetically sealed by, for example, an O-ring (not illustrated).

A choke 84 is formed annularly throughout an inner circumferential surface of the upper portion of the casing 81 in order to prevent the leakage of microwaves from a gap between the lower shaft 20b and the casing 81. The choke 84 is formed in a slit form having, for example, a rectangular cross-sectional shape. In addition, the length L of the choke 84 is set to approximately a quarter of the wavelength of microwaves in order to prevent the leakage of microwaves. In addition, when the inside of the choke 84 is filled with, for example, a dielectric, the length L of the choke 84 may not need to be a quarter of the wavelength of microwaves.

A magnetic fluid seal 85 is provided below the choke 84 on the inner circumferential surface of the casing 81 and serves as a seal member that heimetically seals a gap between the lower shaft 20b of the support shaft 20 and the casing 81. The magnetic fluid seal 85 includes, for example, an annular permanent magnet 85a mounted in the casing 81, and a magnetic fluid 85b sealed between the permanent magnet 85a and the lower shaft 20b. A gap between the support shaft 20 and the processing container 2 is kept hermetically sealed by the magnetic fluid seal 85.

The bearing 80 is provided below the magnetic fluid seal 85 on the support shaft 20. The bearing 80 is supported by the casing 81. Accordingly, the support shaft 20 is supported so as to be freely rotatable relative to the casing 81. Further, while FIG. 3 illustrates only a bearing in a radial direction, a thrust bearing may be provided to support vertical load as needed.

The rotary joint 82 having an annular shape is connected to a lower end of the casing 81. The rotary joint 82 is connected to the lower shaft 20b via a bearing 86, and the lower shaft 20b is freely rotatable relative to the rotary joint 82. A cooling water supply pipe 90 is connected to the side surface of the rotary joint 82, and a cooling water discharge pipe 91 is connected to a position, for example, below the cooling water supply pipe 90. Annular grooves 92 and 93 are formed in the outer circumferential surface of the lower shaft 20b at positions corresponding to the cooling water supply pipe 90 and the cooling water discharge pipe 91, respectively. A cooling water supply path 94 is foamed in the lower shaft 20b to communicate with the groove 92, and extends vertically upward. The cooling water supply path 94 extends to the vicinity of the flange 21, and is folded vertically downward from the vicinity of the flange 21 so as to be connected to the groove 93. A cooling water supply source (not illustrated) is connected to the cooling water supply pipe 90, and cooling water supplied from the cooling water supply source cools the flange 21 through the cooling water supply pipe 90 and the cooling water supply path 94, and thereafter, is discharged from the cooling water discharge pipe 91.

An O-ring 95 is provided vertically on an inner circumferential surface of the rotary joint 82 so as to be fitted into the grooves 92 and 93. Accordingly, cooling water is supplied to the cooling water supply path 94 without leaking from a gap between the rotary joint 82 and the lower shaft 20b.

The slip ring 100 having a cylindrical shape is connected to, for example, a lower end surface of the lower shaft 20b. A disc-shaped rotating electrode 101 is provided in the central portion of a lower end surface of the slip ring 100, and for example, an annular rotating electrode 102 is provided outside the rotating electrode 101. Conductive wires 110 and 111 are electrically connected to the rotating electrodes 101 and 102, respectively, to supply a high-frequency electric power from the high frequency power source 12 to the susceptor 10 or to supply an electric power to the heater inside the susceptor 10. The conductive wires 110 and 111 are provided so as to extend upward along a hollow portion in the support shaft 20 and are connected to the susceptor 10. For the supply of the electric power to the conductive wires 110 and 111, for example, as illustrated in FIG. 3, a power source is connected to the rotating electrodes 101 and 102 via a brush 103. The brush 103 is fixed by, for example, a fixing member (not illustrated) so that a positional relationship thereof relative to the main body portion 2a of the processing container 2 is not changed. Further, while FIG. 3 illustrates the state where the matcher 11 and the high frequency power source 12 are connected to the rotating electrodes 101 and 102 via the brush 103, for example, the placement or the number of the rotating electrodes is not limited to the description of the present exemplary embodiment, and may be arbitrarily set. A device connected to the rotating electrodes may be, for example, a power source for supplying electric power to the heater 13, a power source for applying a voltage to the electrostatic chuck, or a thermocouple mounted in the susceptor 10, which is used to control the temperature of the heater 13.

For example, a shield member 112, which is formed in a cylindrical shape to surround the slip ring 100, is fixed below the rotary joint 82 on the lower shaft 20b. The shield member 112 is formed of, for example, an insulation member to prevent a contact portion of the slip ring 100 and the brush 103 from being exposed.

In addition, a belt 120 is connected to the outer circumference of the shield member 112. A motor 121 is connected to the belt 120 via a shaft 122. Accordingly, as the motor 121 is rotated, the shield member 112 is rotated via the shaft 122 and the belt 120, and the support shaft 20 fixed to the shield member 112 is rotated. In the present disclosure, the rotation driving mechanism 83 is constructed by the shield member 112, the belt 120, and the motor 121. While the slip ring 100 is rotated as the support shaft 20 is rotated, electrical connection with the rotating electrodes 101 and 102 is maintained by the brush 103. In addition, while the cooling water supply path 94 formed in the lower shaft 20b is rotated by rotation of the support shaft 20, connection with the cooling water supply pipe 90 and the cooling water discharge pipe 01 is maintained via the grooves 92 and 93 formed in the lower shaft 20b. Therefore, the supply of cooling water to the cooling water supply path 94 is maintained even when the support shaft 20 is rotated.

Further, while the rotary joint 82 and the rotation driving mechanism 83 are provided in this order below the casing 81 in FIG. 3, the placing or shape thereof may be arbitrarily set so long as the support shaft 20 is appropriately rotated by the rotation driving mechanism 83. In addition, the configuration of the rotation driving mechanism 82 is not limited to the description of the present exemplary embodiment, but the placement of the motor 121 and a mechanism for transmitting drive power of the motor 121 to the support shaft 20 may be arbitrarily set.

In this way, the rotary seal mechanism 35 moves the susceptor 10 relative to the rod-shaped members 46 by rotating the susceptor 10 via the support shaft 20. That is, the rotary seal mechanism 35 moves the rod-shaped members 46 and the susceptor 10 relative to each other by rotating the susceptor 10. Accordingly, a uniform plasma processing may be performed on the entire processing target surface of the wafer W because ions in plasma may be incident uniformly on the wafer W on the susceptor 10 from an inclined direction.

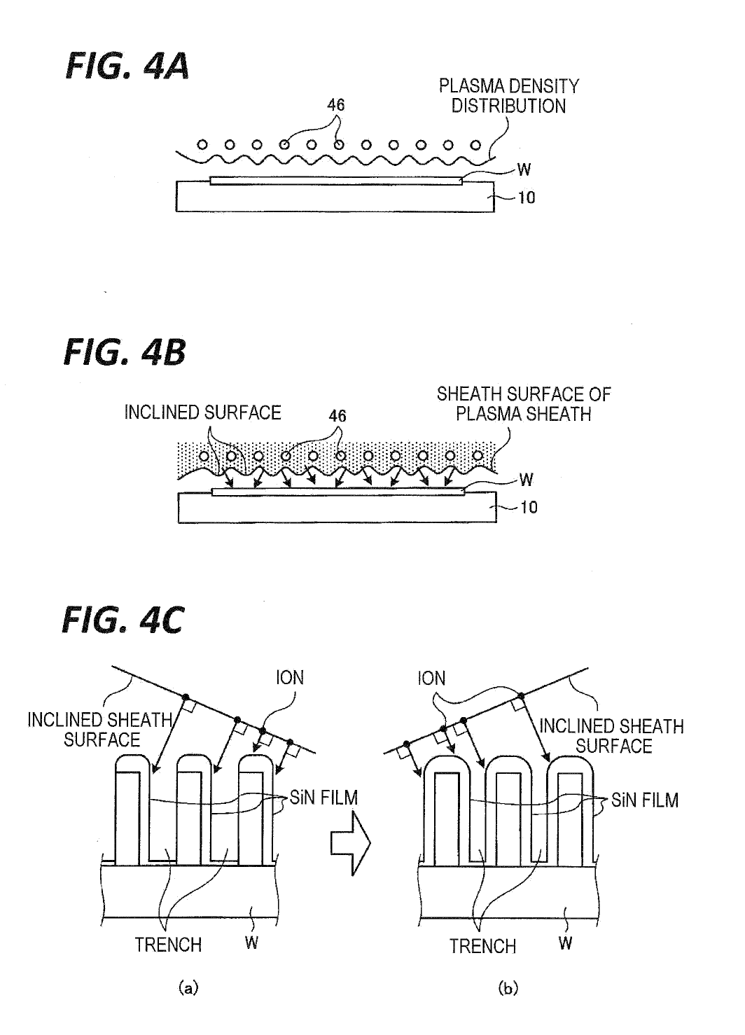

Here, a mechanism for uniformizing a plasma processing using relative movement of the plurality of rod-shaped members 46 and the susceptor 10 will be described in detail. FIGS. 4A to 4C are views for explaining a mechanism for uniformizing a plasma processing using relative movement of the plurality of rod-shaped members and the susceptor according to an exemplary embodiment.

As described above, the plurality of rod-shaped members 46 are provided at a position closer to the susceptor 10 than an intermediate position between the susceptor 10 and the radial line slot antenna 40. The plurality of rod-shaped members 46 shield some of the plasma generated between the susceptor 10 and the radial line slot antenna 40. When some of the plasma is shielded by the plurality of rod-shaped members 46, as illustrated in FIG. 4A, the plasma density is reduced in a region between the plurality of rod-shaped members 46 and the susceptor 10, and the distribution of the plasma density becomes uneven above the processing target surface of the wafer W.

Here, it is known that, when the electric power of the plasma is constant, the plasma density is inversely proportional to the potential of plasma sheath (hereinafter, referred to as “sheath potential”) formed above the processing target surface of the wafer W. Therefore, when the distribution of the plasma density is uneven, the distribution of sheath potential acquired by reversing the distribution of the plasma density is also uneven. Thus, as illustrated in FIG. 4B, the sheath surface of the plasma sheath has a shape including an inclined surface (hereinafter, referred to as an “inclined sheath surface”), which is inclined with respect to the processing target surface of the wafer W. In this way, as illustrated in FIG. 4C, ions in the plasma are accelerated in a direction perpendicular to the inclined sheath surface, and the accelerated ions in the plasma are incident on the processing target surface of the wafer W from the inclined direction. Accordingly, the ions in the plasma are irradiated from the inclined direction to a “partial surface” in a peripheral direction of the wafer W of the side portion of the trench in the wafer W, and an SiN film is formed on the “partial surface” of the side portion of the trench in the wafer W.

Then, when the rotary seal mechanism 35 moves the plurality of rod-shaped members 46 and the susceptor 10 relative to each other by rotating the susceptor 10, a positional relationship between the inclined sheath surface and the wafer W on the susceptor 10 is changed. Accordingly, as illustrated in (b) of FIG. 4C, the ions in the plasma are irradiated from the inclined direction to “another surface”, which is different from the “partial surface”, of the side portion of the trench in the wafer W, and an SiN film is formed on the “another surface” of the side portion of the trench in the wafer W. That is, since the ions in the plasma are uniformly irradiated from the inclined direction to the side portion of the trench in the wafer W as the rotary seal mechanism 35 moves the plurality of rod-shaped members 46 and the susceptor 10 relative to each other, the uniformity of the film forming speed in the peripheral direction of the wafer W is maintained. In this way, a uniform plasma processing is performed on the entire processing target surface of the wafer W.

As described above, in the plasma processing apparatus of the present exemplary embodiment, the plurality of rod-shaped members 46 are provided at a position closer to the susceptor 10 than an intermediate position between the susceptor 10 and the radial line slot antenna 40, and the plurality of rod-shaped members 46 and the susceptor 10 are moved relative to each other. Accordingly, the ions in the plasma may be incident uniformly on the wafer W on the susceptor 10 form the inclined direction, and consequently, a uniform plasma processing may be performed on the entire processing target surface of the wafer W.

In addition, the disclosed technology is not limited to the exemplary embodiment, and various modifications may be made within the scope of the present disclosure.

In the exemplary embodiment, descriptions has been made on an example in which the susceptor 10 is moved relative to the plurality of rod-shaped members 46 as the rotary seal mechanism 35 as a moving mechanism rotates the susceptor 10. However, the method of moving the plurality of rod-shaped members 46 and the susceptor 10 relative to each other is not limited thereto. For example, the moving mechanism may move the plurality of rod-shaped members 46 relative to the susceptor 10 by reciprocating the plurality of rod-shaped members 46 in a direction parallel to the susceptor 10, which is a direction intersecting with the plurality of rod-shaped members 46 when the rod-shaped members 46 are of a movable type. Accordingly, similarly to the exemplary embodiment, the ions in the plasma may be incident uniformly on the wafer W on the susceptor 10 from the inclined direction, and consequently, a uniform plasma processing may be performed on the entire processing target surface of the wafer W. In addition, for example, when the plurality of rod-shaped members 46 are of a movable type, the moving mechanism may move the plurality of rod-shaped members 46 and the susceptor 10 relative to each other by moving both the plurality of rod-shaped members 46 and the susceptor 10.

In addition, in the exemplary embodiment, descriptions has been made on an example in which the plurality of rod-shaped members 46 are provided at a position closer to the susceptor 10 than an intermediate position between the susceptor 10 and the radial line slot antenna 40. However, the disclosed technology is not limited thereto. For example, a lattice-shaped member may be provided at the position closer to the intermediate position between the susceptor 10 and the radial line slot antenna 40. In this case, the distance between the lattice-shaped member and the susceptor 10 is set to a value equal to or less than the pitch of the lattice-shaped member (i.e., the distance between neighboring lattices). In this case, the rotary seal mechanism 35 moves the susceptor 10 relative to the lattice-shaped member by rotating the susceptor 10. Accordingly, similarly to the exemplary embodiment, the ions in the plasma may be incident uniformly on the wafer W on the susceptor 10 from the inclined direction, and consequently, a uniform plasma processing may be performed on the entire processing target surface of the wafer W.

In addition, in another exemplary embodiment, the plasma processing apparatus 1 may include a tilt mechanism configured to tilt the susceptor 10 relative to the radial line slot antenna 40. In this case, the rotary seal mechanism 35 moves the susceptor 10 relative to the plurality of rod-shaped members 46 by further rotating the susceptor 10 tilted by the tilt mechanism. Accordingly, the ions in the plasma may be incident uniformly on the wafer W on the susceptor 10 from the inclined direction, and consequently, a uniform plasma processing may be performed on the entire processing target surface of the wafer W. In addition, the tilt angle of the susceptor 10 relative to the radial line slot antenna 40 may be adjustable.

In addition, in the exemplary embodiment, descriptions has been mande on the case where the disclosed technology is applied to the plasma processing apparatus 1, which performs film formation using plasma on the wafer W. Howevver, an object to which the disclosed technology is applied is not limited thereto. For example, the disclosed technology may be applied to, for example, an apparatus for performing etching using plasma, or an apparatus for reforming a film stacked on the wafer W using plasma.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container;
a placing table provided in the processing container and configured to place a substrate thereon;
a plasma generating mechanism attached to the processing container to face the placing table and configured to supply electronic energy for plasma generation into the processing container;
a lattice-shaped member or a plurality of rod-shaped members provided at a position closer to the placing table than an intermediate position between the placing table and the plasma generating mechanism; and
a moving mechanism configured to move the lattice-shaped member or the plurality of rod-shaped members and the placing table relative to each other.

2. The plasma processing apparatus of claim 1, wherein the moving mechanism moves the placing table relative to the lattice-shaped member or the plurality of rod-shaped members by rotating the placing table.

3. The plasma processing apparatus of claim 1, wherein the moving mechanism moves the plurality of rod-shaped members relative to the placing table by reciprocating the plurality of rod-shaped members in a direction parallel to the placing table, which is a direction intersecting with the plurality of rod-shaped members.

4. The plasma processing apparatus of claim 1, wherein a distance between the lattice-shaped member or the plurality of rod-shaped members and the placing table is equal to or less than a pitch of the lattice-shaped member or the plurality of rod-shaped members.

5. The plasma processing apparatus of claim 1, further comprising:
a high frequency power source configured to apply a bias electric power to the placing table.
